(19) United States
(12) Patent Application Publication
(10) Pub. No.: US 2026/0063669 A1
(43) Pub. Date: Mar. 5, 2026

(54) PROBE UNIT, PROBE HEAD, PROBE CARD, PROBE SYSTEM, METHOD OF PERFORMING A TEST ON AN ELECTRONIC DEVICE UNDER TEST, AND TESTED ELECTRONIC DEVICE

(71) Applicant: MPI CORPORATION, CHU-PEI CITY (TW)

(72) Inventors: CHIN-YI LIN, CHU-PEI CITY (TW); CHE-WEI LIN, CHU-PEI CITY (TW); YUN-HUI SHEN, CHU-PEI CITY (TW); CHIH-MING HUANG, CHU-PEI CITY (TW); TSUNG-YI CHEN, CHU-PEI CITY (TW)

(73) Assignee: MPI CORPORATION, CHU-PEI CITY (TW)

(21) Appl. No.: 19/314,796

(22) Filed: Aug. 29, 2025

Related U.S. Application Data
(60) Provisional application No. 63/689,962, filed on Sep. 3, 2024.

(51) Int. Cl. G01R 1/073; G01R 1/067; G01R 31/28

(52) U.S. Cl. CPC G01R 1/07342; G01R 1/06755; G01R 1/07378; G01R 31/2886

(57) ABSTRACT

A probe unit includes first and second probes of equal length. A probe body of at least one of the probes has a slot extending along a longitudinal direction thereof to define two slats. A total cross-sectional area of the slats of the first probe is greater than that of the second probe. Alternatively, the probe body of the second probe is solid, and the total cross-sectional area of the slats of the first probe is greater than the cross-sectional area of the solid probe body of the second probe. The slats are shaped in such a way that a contact force of the first probe is greater than that of the second probe, thereby meeting testing requirements of conductive contacts of different sizes on an electronic device under test, while reducing problems of different probe tip wear rates and excessive probe mark area ratio differences.

### CROSS REFERENCE TO RELATED APPLICATIONS

This non-provisional application claims the benefit under 35 U.S.C. § 119 (e) to U.S. Provisional Application No. 63/689,962, filed on Sep. 3, 2024, which is hereby expressly incorporated by reference into the present application.

### BACKGROUND OF THE INVENTION

### 1. Field of the Invention

The present invention relates generally to probes of a probe card and more particularly, to a probe unit including probes of different shapes, as well as a probe head, a probe card, and a probe system using the probe unit. The present also relates to a method of performing a test on an electronic device under test and a tested electronic device, which use the probe system.

### 2. Description of the Related Art

Conventionally, when testing devices on a wafer, a probe card is generally used to transmit signals between a device under test (DUT) and a tester. The probe card is provided with a plurality of probes for respectively contacting a plurality of conductive contacts of the device under test. The conductive contacts may be realized, for example, as pads or bumps. Some conductive contacts of the device under test have different current requirements and different sizes. Typically, high current corresponds to larger conductive contacts, which are spaced farther apart, while low current corresponds to smaller conductive contacts, which are spaced closer together. Therefore, if the probe card is provided only with small-sized probes, the conductive contact force and current-carrying capacity will be insufficient for conductive contacts with larger size and high current demand. Conversely, if the probe card is provided only with large-sized probes, the excessive probe force may damage conductive contacts with smaller size and low current demand.

Reference is made to US Patent Publication No. 20200166541A1, which corresponds to Taiwan Patent No. 1695549, and discloses a solution of simultaneously using probes of different cross-sectional areas, that is, simultaneously using large-sized probes and small-sized probes. Although this may solve the above-mentioned problems, the probes disclosed therein have substantially a same bending rigidity and thus produce the same contact force. In other words, the probes contact conductive contacts of different sizes on the device under test with the same contact force, which results in inconsistent probe tip wear rates and/or excessively large differences in probe mark area ratios.

Specifically, the probe tip wear rate depends on the contact force per unit area. When large-sized probes and small-sized probes respectively contact large conductive contacts and small conductive contacts with the same contact force, the probe tip wear rate of the small-sized probes is higher than that of the large-sized probes. The probe mark area ratio refers to the ratio of the area of a trace formed by flattening the top of a bump with a probe to the cross-sectional area of the bottom of the bump, when the conductive contacts of the device under test are bumps. When large-sized probes and small-sized probes respectively contact large bumps and small bumps with the same contact force, the probe mark area ratio produced by the small-sized probes is greater than that produced by the large-sized probes, resulting in inconsistent heights of the large bumps and the small bumps after testing.

### SUMMARY OF THE INVENTION

The present invention has been accomplished in view of the above-noted circumstances. The present invention discloses a probe unit, a probe head, a probe card, and a probe system, in which probes having different cross-sectional areas are hybridly used (i.e., hybrid use of probes), and which is capable of suppressing adverse effects caused by differences in wear rates of probe tips, and also of controlling the difference in probe mark area ratio within an acceptable range.

The present invention discloses a probe unit for contacting a plurality of conductive contacts of an electronic device under test integrated in a semiconductor wafer. The probe unit comprises a plurality of probes each having the same length, each probe including a probe tail and a probe tip respectively located at two ends thereof, and a probe body between the probe tail and the probe tip. The probe body comprises at least one slot extending along a longitudinal direction thereof and penetrating through the probe body along a first transverse axis, such that the probe body is hollow and defined by the at least one slot with at least two slats separated from each other along a second transverse axis and elastically bendable under an applied load. Each of the slats has a cross-sectional area on an imaginary plane parallel to the first transverse axis and the second transverse axis, and a sum of the cross-sectional areas of the at least two slats of each of the probes is defined as a total cross-sectional area. The plurality of probes include a first probe and a second probe, the total cross-sectional area of the slats of the first probe is greater than the total cross-sectional area of the slats of the second probe, the slats of the first probe have shapes different from that of the slats of the second probe, and the shapes of the slats of the first and second probe are configured such that a contact force of the first probe is greater than a contact force of the second probe.

Accordingly, the present invention adopts a hybrid probe configuration, that is, at least two types of probes, namely the first probe and the second probe, are used simultaneously. The width and thickness of the first and second probes may be designed according to the sizes and pitches of the conductive contacts of the electronic device to be contacted, and the rigidity of the probes can be appropriately reduced through the design of the slots of the probe body (designed slot width, number, etc.), thereby appropriately reducing the contact force of the probes so that the first and second probes meet the testing requirements of the respective conductive contacts. Specifically, the total cross-sectional area of the slats of the first probe is larger, which can satisfy the high current demand of larger conductive contacts, and the larger conductive contacts can withstand the larger contact force of the first probe without being easily damaged. The total cross-sectional area of the slats of the second probe is smaller, which can satisfy the low current demand of smaller conductive contacts, and the smaller contact force of the second probe can prevent damage to the smaller conductive contacts. More importantly, the first and second probes can respectively contact larger and smaller conductive contacts with larger and smaller contact forces, so that through dimensional design, the ratio of contact force to contact area of the first and second probes can be made consistent or similar, thereby making the wear rates of the probe tips of the first and second probes consistent or similar, and thus maintaining consistent or similar lengths of the first and second probes. Moreover, through dimensional design, the first and second probes can produce consistent or similar probe mark area ratios on large bumps and small bumps of the electronic device under test, so that the large bumps and the small bumps may have consistent or similar heights after testing.

Preferably, a ratio of the contact force of the first probe to the contact force of the second probe is greater than 1 and less than 4. In this way, the requirements of most wafer tests can be satisfied.

Preferably, the probe body of each of the probes defines a thickness along the first transverse axis and a width along the second transverse axis, and the width of the probe body of each of the probes is less than or equal to the thickness.

In other words, the cross-sectional shape of the probe may be square or rectangular, with the longer side of the rectangle being the thickness direction of the probe, namely the first transverse axis. Since the slot of the probe penetrates through the probe body along the first transverse axis, when the probe is in use, its probe body bends along the second transverse axis, i.e., the axis defining the width. A square cross-section probe can not only better conform to the shape of the conductive contacts of the electronic device under test, but also ensures that the width of the probe body is not greater than the thickness, which is advantageous to elastic deformation in bending along the second transverse axis. A rectangular cross-section probe, in which the width of the probe body is smaller than the thickness, achieves an even better elastic bending deformation effect along the second transverse axis. Moreover, making the width of the probe body smaller than or equal to the thickness allows the probe body to have sufficient thickness to maintain a certain current-carrying capacity.

Preferably, the probe tip of the first probe comprises a base portion connected to the probe body and an end portion connected to the base portion. The end portion is configured for contacting the conductive contact of the electronic device under test. The base portion and the end portion respectively define cross-sectional areas on an imaginary plane parallel to the first transverse axis and the second transverse axis, wherein the cross-sectional area of the end portion is smaller than the cross-sectional area of the base portion.

In other words, the probe tip of the first probe has a thinned and/or narrowed end portion. That is, the base portion may have the same outer contour dimensions as the probe body, while the end portion is further reduced in thickness and/or width compared to the base portion, such that the cross-sectional area of the end portion is smaller than the cross-sectional area of the base portion. Such a structural design also helps adjust the wear rate of the probe tip of the first probe and the probe mark area ratio generated thereby, so that the wear rates of the probe tips of the first and second probes may be consistent or similar, and the probe marks generated by the first and second probes may have consistent or similar area ratios.

More preferably, the probe tip of the second probe defines a cross-sectional area on an imaginary plane parallel to the first transverse axis and the second transverse axis, and the cross-sectional area of the end portion of the probe tip of the first probe is greater than or equal to the cross-sectional area of the probe tip of the second probe.

Accordingly, when the first and second probes contact the conductive contacts of the electronic device under test, the contact area of the first probe is greater than or equal to the contact area of the second probe. Such a structural design also helps make the wear rates of the probe tips of the first and second probes consistent or similar, and make the probe marks generated by the first and second probes have consistent or similar area ratios.

More preferably, a ratio of the cross-sectional area of the end portion of the probe tip of the first probe to the cross-sectional area of the probe tip of the second probe is greater than 1 and less than 4. In this way, the requirements of most wafer tests can be satisfied.

Preferably, the plurality of conductive contacts of the electronic device under test include a first bump and a second bump, and a maximum cross-sectional area of the first bump is greater than a maximum cross-sectional area of the second bump. When the probe tip of the first probe and the probe tip of the second probe respectively press against the first bump and the second bump so that the probe body of the first probe and the probe body of the second probe are subjected to a load and elastically bent, the first probe forms a first probe mark area on the first bump, and the second probe forms a second probe mark area on the second bump, and a ratio of the first probe mark area to the maximum cross-sectional area of the first bump and a ratio of the second probe mark area to the maximum cross-sectional area of the second bump are substantially equal.

Accordingly, when the conductive contacts of the electronic device under test are bumps, the first and second probes form substantially equal probe mark area ratios on a large bump (i.e., the first bump) and a small bump (i.e., the second bump), respectively. The term “substantially equal” is defined as having a difference less than or equal to 20%. In this way, the first and second bumps may have consistent or similar heights after testing.

Alternatively, the plurality of conductive contacts of the electronic device under test may include a plurality of first bumps and a second bump, and each of the plurality of first bumps has substantially the same size as the second bump. The probe tip of the first probe is for simultaneously pressing against the plurality of first bumps, the plurality of first bumps being configured to transmit a first signal, the first signal being one of a power signal and a ground signal. The probe tip of the second probe is for pressing against the second bump, the second bump being configured to transmit a second signal different from the first signal, the second signal being a test signal.

Accordingly, even if each of the first bumps and the second bump have substantially the same size, the first probe having a larger contact force is for simultaneously pressing against the plurality of first bumps, and the second probe having a smaller contact force is for pressing against the single second bump. Therefore, through dimensional design, the wear rates of the probe tips of the first and second probes can still be made consistent or similar, and/or consistent or similar probe mark area ratios can be produced on the first bumps and the second bump.

Preferably, the probe body of each of the probes defines a thickness along the first transverse axis and a width along the second transverse axis, and a ratio of the width to the thickness of the probe body of the first probe is smaller than a ratio of the width to the thickness of the probe body of the second probe.

Accordingly, a smaller ratio of the width to the thickness of the probe body of the first probe is advantageous to improving its elastic bending deformation effect along the second transverse axis, such that the probe body of the first probe having a larger total cross-sectional area and the probe body of the second probe having a smaller total cross-sectional area can achieve consistent or similar elastic deformation effects, thereby providing consistent or similar probing performance.

Preferably, the first probe and the second probe have different material hardness.

Accordingly, the first probe and the second probe may be made of materials having different hardness. For example, the second probe having a smaller total cross-sectional area may be made of a harder material to slow down its probe tip wear rate. In this way, the wear rates of the probe tips of the first and second probes can also be made consistent or similar.

More preferably, the material hardness of the second probe is greater than the material hardness of the first probe.

Accordingly, when the second probe having a smaller total cross-sectional area is made of a harder material, its probe tip wear rate can be slowed down, thereby contributing to making the wear rates of the probe tips of the first and second probes consistent or similar.

Preferably, at least the slot of the first probe is disposed with at least one protrusion set (that is, at least one protrusion set may also be disposed in the slot of the second probe, or no protrusion set may be disposed in the slot of the second probe). The protrusion set comprises two protrusions protruding from two adjacent slats toward each other.

Accordingly, when the slats of the probe body are subjected to a load and elastically bent, the two protrusions facing each other in the slot abut against each other, thereby preventing the adjacent slats from contacting and wearing against each other, and thus extending the service life of the probe. Moreover, by the two protrusions facing each other and abutting against each other, the slats can be kept in a consistent deflection direction and maintained at a certain interval, which contributes to electrical performance in high-frequency and high-speed testing.

The present invention further provides another probe unit for contacting a plurality of conductive contacts of an electronic device under test integrated in a semiconductor wafer. The probe unit comprises a plurality of probes each having a same length and each including a probe tail and a probe tip respectively located at two ends thereof, and a probe body between the probe tail and the probe tip. The plurality of probes include a first probe and a second probe. The probe body of the first probe comprises at least one slot extending along a longitudinal direction thereof and penetrating through the probe body of the first probe along a first transverse axis, such that the probe body of the first probe is hollow and defined by the at least one slot with at least two slats separated from each other along a second transverse axis and elastically bendable under an applied load. The probe body of the second probe is solid and elastically bendable under an applied load. The probe tail and the probe tip of each of the probes, each of the slats of the first probe, and the probe body of the second probe respectively define a cross-sectional area on an imaginary plane parallel to the first transverse axis and the second transverse axis, and a sum of the cross-sectional areas of the at least two slats of the first probe is defined as a total cross-sectional area. The total cross-sectional area of the slats of the first probe is greater than the cross-sectional area of the probe body of the second probe. The cross-sectional area of the probe body of the second probe is smaller than the cross-sectional area of the probe tail of the second probe and smaller than the cross-sectional area of the probe tip of the second probe. Shapes of the slats of the first probe are configured such that a contact force of the first probe is greater than a contact force of the second probe.

Accordingly, the present invention adopts a hybrid probe configuration, that is, at least two types of probes, namely the first probe and the second probe, are used simultaneously. The width and thickness of the first and second probes may be designed according to the sizes and pitches of the conductive contacts of the electronic device to be contacted. In addition, the first probe can appropriately reduce its rigidity, and thereby appropriately reduce its contact force, through the design of the width of the slot of its probe body, while the second probe can appropriately reduce its rigidity, and thereby appropriately reduce its contact force, through reducing the cross-sectional area of its probe body relative to its probe tail and probe tip. In other words, although the probe body of the first probe is hollow and the probe body of the second probe is solid, both can, through the design of the cross-sectional areas of the probe bodies of the first and second probes, satisfy the testing requirements of the respective conductive contacts in all aspects. Specifically, the total cross-sectional area of the slats of the first probe is larger, which can satisfy the high current demand of larger conductive contacts, and the larger conductive contacts can withstand the larger contact force of the first probe without being easily damaged. The cross-sectional area of the probe body of the second probe is smaller, which can satisfy the low current demand of smaller conductive contacts, and the smaller contact force of the second probe can prevent damage to the smaller conductive contacts. More importantly, the first and second probes can respectively contact larger and smaller conductive contacts with larger and smaller contact forces, so that through dimensional design, the ratio of contact force to contact area of the first and second probes can be made consistent or similar, thereby making the wear rates of the probe tips of the first and second probes consistent or similar, and thus maintaining consistent or similar lengths of the first and second probes. Moreover, through dimensional design, the first and second probes can produce consistent or similar probe mark area ratios on large bumps and small bumps of the electronic device under test, so that the large bumps and the small bumps have consistent or similar heights after testing.

Preferably, the probe body of the first probe defines a thickness along the first transverse axis and a width along the second transverse axis, and the width of the probe body of the first probe is less than or equal to the thickness.

In other words, the cross-sectional shape of the first probe may be square or rectangular, with the longer side of the rectangle being the thickness direction of the probe, namely the first transverse axis. Since the slot of the first probe penetrates through the probe body along the first transverse axis, when the probe is in use, its probe body bends along the second transverse axis, i.e., the axis defining the width. A square cross-section probe can not only better conform to the shape of the conductive contacts of the electronic device under test, but also ensures that the width of the probe body is not greater than the thickness, which is advantageous to elastic deformation in bending along the second transverse axis. A rectangular cross-section probe, in which the width of the probe body is smaller than the thickness, achieves an even better elastic bending deformation effect along the second transverse axis. Moreover, making the width of the probe body smaller than or equal to the thickness allows the probe body to have sufficient thickness to maintain a certain current-carrying capacity.

Preferably, the first probe and the second probe have different material hardness.

Accordingly, the first probe and the second probe may be made of materials having different hardness. For example, the second probe having a smaller cross-sectional area may be made of a harder material to slow down its probe tip wear rate. In this way, the wear rates of the probe tips of the first and second probes can also be made consistent or similar.

More preferably, the material hardness of the second probe is greater than the material hardness of the first probe.

Accordingly, when the second probe having a smaller total cross-sectional area is made of a harder material, its probe tip wear rate can be slowed down, thereby contributing to making the wear rates of the probe tips of the first and second probes consistent or similar.

Preferably, at least one protrusion set is disposed in the slot of the first probe, and the protrusion set comprises two protrusions protruding from two adjacent slats toward each other.

Accordingly, when the slats of the probe body of the first probe are subjected to a load and elastically bent, the two protrusions facing each other in the slot abut against each other, thereby preventing the adjacent slats from contacting and wearing against each other, and thus extending the service life of the first probe. Moreover, by the two protrusions facing each other and abutting against each other, the slats can be kept in a consistent deflection direction and maintained at a certain interval, which contributes to electrical performance in high-frequency and high-speed testing.

Preferably, in each of the probe units described above, the first probe and the second probe have different resistance values.

Accordingly, the first probe and the second probe can be designed to have different resistance values through their materials, shapes, sizes, and the like, so as to be applicable to different currents and thereby satisfy the testing requirements of different conductive contacts. At the same time, the first probe and the second probe can still be designed such that their contact forces make the wear rates of their probe tips consistent or similar, and/or produce consistent or similar probe mark area ratios on the conductive contacts contacted thereby.

More preferably, in each of the probe units described above, the resistance value of the first probe is smaller than the resistance value of the second probe.

Accordingly, the first probe can be applied to larger currents, meeting the high current demand of larger conductive contacts, and the larger conductive contacts can withstand the larger contact force of the first probe without being easily damaged. The second probe can be applied to smaller currents, meeting the low current demand of smaller conductive contacts, and the smaller contact force of the second probe can prevent damage to the smaller conductive contacts.

Preferably, in each of the probe units described above, the first probe and the second probe have different current-carrying capacity.

Accordingly, the first probe and the second probe can be designed, through their materials, shapes, sizes, and the like, to have different current-carrying capacity so as to meet the current requirements of different conductive contacts. At the same time, the first probe and the second probe can still be designed such that their contact forces make the wear rates of their probe tips consistent or similar, and/or produce consistent or similar probe mark area ratios on the conductive contacts contacted thereby.

Preferably, in each of the probe units described above, the first probe and the second probe have different resistivity.

Accordingly, the first probe and the second probe may be made of different materials having different resistivity, so that material differences achieve optimized design of the first and second probes under different current conditions. For example, a probe for high current demand may adopt a material of low resistivity to reduce Joule heat loss, while a probe for low current demand may adopt a material of better mechanical strength to improve service life and accuracy.

Preferably, in each of the probe units described above, the first probe and the second probe have different conductivity.

Accordingly, the first probe and the second probe may be made of different materials having different conductivity, so that material differences achieve optimized design of the first and second probes under different current conditions. A material with higher conductivity is more conductive, and thus a probe for high current demand may adopt a material of high conductivity, while a probe for low current demand may adopt a material of better mechanical strength to improve service life and accuracy.

Preferably, in each of the probe units described above, a ratio of the contact force of the first probe to the contact force of the second probe is greater than 1 and less than 4. In this way, the requirements of most wafer tests can be satisfied.

Preferably, in each of the probe units described above, the probe tip of the first probe comprises a base portion connected to the probe body and an end portion connected to the base portion. The end portion is configured for contacting the conductive contact of the electronic device under test. The base portion and the end portion respectively define cross-sectional areas on an imaginary plane parallel to the first transverse axis and the second transverse axis, wherein the cross-sectional area of the end portion is smaller than the cross-sectional area of the base portion.

In other words, the probe tip of the first probe has a thinned and/or narrowed end portion. That is, the base portion may have the same outer contour dimensions as the probe body, while the end portion is further reduced in thickness and/or width compared to the base portion, such that the cross-sectional area of the end portion is smaller than the cross-sectional area of the base portion. Such a structural design also helps adjust the wear rate of the probe tip of the first probe and the probe mark area ratio generated thereby, so that the wear rates of the probe tips of the first and second probes may be consistent or similar, and the probe marks generated by the first and second probes may have consistent or similar area ratios.

More preferably, in each of the probe units described above, the probe tip of the second probe defines a cross-sectional area on an imaginary plane parallel to the first transverse axis and the second transverse axis, and the cross-sectional area of the end portion of the probe tip of the first probe is greater than or equal to the cross-sectional area of the probe tip of the second probe.

Accordingly, when the first and second probes contact the conductive contacts of the electronic device under test, the contact area of the first probe is greater than or equal to the contact area of the second probe. Such a structural design also helps make the wear rates of the probe tips of the first and second probes consistent or similar, and make the probe marks generated by the first and second probes have consistent or similar area ratios.

More preferably, in each of the probe units described above, a ratio of the cross-sectional area of the end portion of the probe tip of the first probe to the cross-sectional area of the probe tip of the second probe is greater than 1 and less than 4. In this way, the requirements of most wafer tests can be satisfied.

Preferably, in each of the probe units described above, the plurality of conductive contacts of the electronic device under test include a first bump and a second bump, and a maximum cross-sectional area of the first bump is greater than a maximum cross-sectional area of the second bump. When the probe tip of the first probe and the probe tip of the second probe respectively press against the first bump and the second bump so that the probe body of the first probe and the probe body of the second probe are subjected to a load and elastically bent, the first probe forms a first probe mark area on the first bump, and the second probe forms a second probe mark area on the second bump, and a ratio of the first probe mark area to the maximum cross-sectional area of the first bump and a ratio of the second probe mark area to the maximum cross-sectional area of the second bump are substantially equal.

Accordingly, when the conductive contacts of the electronic device under test are bumps, the first and second probes form substantially equal probe mark area ratios on a large bump (i.e., the first bump) and a small bump (i.e., the second bump), respectively. The term “substantially equal” is defined as having a difference less than or equal to 20%. In this way, the first and second bumps may have consistent or similar heights after testing.

Alternatively, in each of the probe units described above, the plurality of conductive contacts of the electronic device under test may include a plurality of first bumps and a second bump, and each of the plurality of first bumps has substantially the same size as the second bump. The probe tip of the first probe is for simultaneously pressing against the plurality of first bumps, the plurality of first bumps being configured to transmit a first signal, the first signal being one of a power signal and a ground signal. The probe tip of the second probe is for pressing against the second bump, the second bump being configured to transmit a second signal different from the first signal, the second signal being a test signal.

Accordingly, even if each of the first bumps and the second bump have substantially the same size, the first probe having a larger contact force is for simultaneously pressing against the plurality of first bumps, and the second probe having a smaller contact force is for pressing against the single second bump. Therefore, through dimensional design, the wear rates of the probe tips of the first and second probes can still be made consistent or similar, and/or consistent or similar probe mark area ratios can be produced on the first bumps and the second bump.

Preferably, in each of the probe units described above, the probe body of each of the probes defines a thickness along the first transverse axis and a width along the second transverse axis, and a ratio of the width to the thickness of the probe body of the first probe is smaller than a ratio of the width to the thickness of the probe body of the second probe.

Accordingly, a smaller ratio of the width to the thickness of the probe body of the first probe is advantageous to improving its elastic bending deformation effect along the second transverse axis, such that the probe body of the first probe having a larger total cross-sectional area and the probe body of the second probe having a smaller cross-sectional area can achieve consistent or similar elastic deformation effects, thereby providing consistent or similar probing performance.

The present invention further provides a probe head applied to a probe system for testing an electronic device under test integrated in a semiconductor wafer. The probe head comprises an upper guide unit, a lower guide unit, and a probe unit as described above. The upper guide unit comprises a plurality of upper guide holes, and the lower guide unit comprises a plurality of lower guide holes. The probe tails of the plurality of probes are respectively inserted through the upper guide holes, the probe tips of the plurality of probes are respectively inserted through the lower guide holes, and the probe bodies of the plurality of probes bend along the second transverse axis.

The present invention further provides a probe card applied to a probe system for testing an electronic device under test integrated in a semiconductor wafer. The probe card comprises a probe head as described above, a space transformer, and a main circuit board. The space transformer is disposed on a lower surface of the main circuit board, and the space transformer comprises a lower surface and a plurality of contact pads on the lower surface. The probe tails of the plurality of probes of the probe head mechanically and electrically contact the contact pads of the space transformer.

The present invention further provides a probe system for testing an electronic device under test integrated in a semiconductor wafer. The probe system comprises a chuck for supporting the electronic device under test, a tester, and a probe card as described above. The probe card is electrically connected with the tester and configured to contact the electronic device under test so as to electrically connect the tester to the electronic device under test and thereby perform an electrical test procedure.

The present invention further provides a method for testing an electronic device under test, which comprises the steps of:
(a) providing the probe system as describes above;
(b) positioning the probe head at a relative position with respect to the electronic device under test; and
(c) pressing the probe head against the electronic device under test to contact the electronic device under test and detecting an electrical characteristic of the electronic device under test.

The present invention further provides an electronic device, which is tested by the method as described above.

Accordingly, the probe head, probe card, probe system, test method, and tested electronic device provided by the present invention adopt the probe unit as described above, and thus have the advantages and effects thereof. Probes of different cross-sectional areas can be used to satisfy the testing requirements of conductive contacts of different sizes of the electronic device under test, while simultaneously avoiding the problems of different probe tip wear rates and excessively large differences in probe mark area ratios.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic view of a probe system according to a first preferred embodiment of the present invention together with a semiconductor wafer;

FIG. 2 is a top schematic view of an electronic device under test on the semiconductor wafer;

FIG. 3 is a schematic sectional view of parts of a probe head and a space transformer of the probe system according to the first preferred embodiment of the present invention;

FIG. 4 is a cross-sectional view of probe bodies of first and second probes of the probe head;

FIG. 5 is a schematic view of parts of the first and second probes and the electronic device under test;

FIG. 6 is a schematic view of a part of the electronic device under test, showing a state in which first and second bumps of the electronic device under test are respectively pressed by the first and second probes;

FIG. 7 is a view similar to FIG. 4, but showing first and second probes of different configurations;

FIG. 8 is a schematic view of another configuration of the first probe;

FIG. 9 is a schematic sectional view taken along line 9-9 of FIG. 8;

FIG. 10 is a schematic sectional view of a part of a probe head according to a second preferred embodiment of the present invention;

FIG. 11 is a schematic sectional view of a part of a probe head according to a third preferred embodiment of the present invention;

FIG. 12 is a cross-sectional view of probe bodies of first and second probes of the probe head according to the third preferred embodiment of the present invention; and

FIG. 13 is a schematic view showing that the first and second probes are to contact first and second bumps of substantially the same size.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

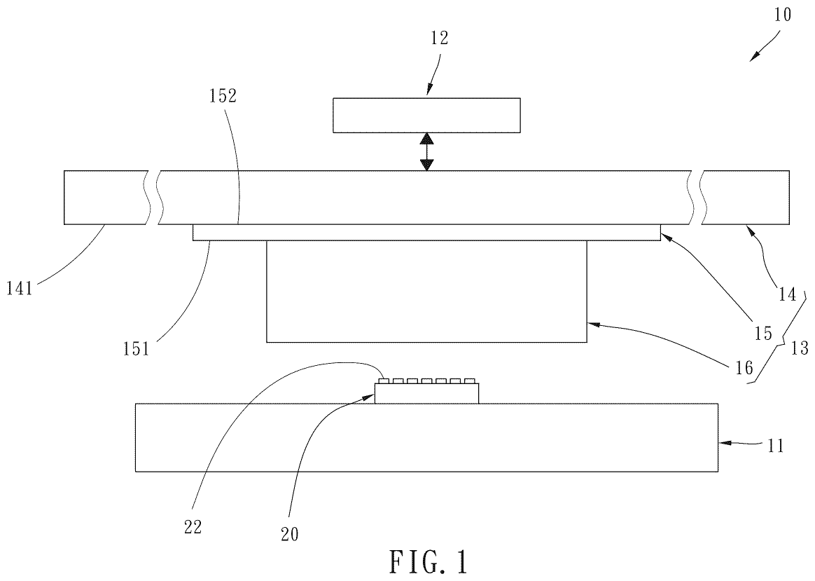

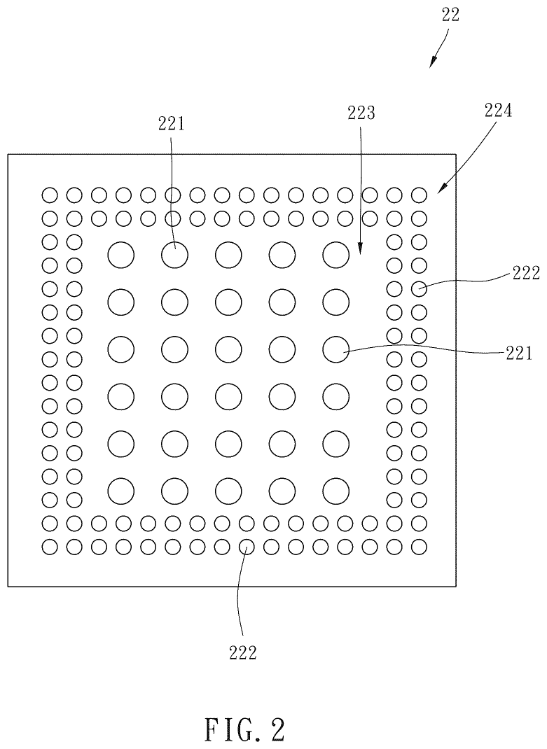

Referring to FIG. 1, a probe system 10 provided by a first preferred embodiment of the present invention is adapted for testing a plurality of electronic devices 22 under test (DUTs 22) integrated in a semiconductor wafer 20. As shown in FIG. 2, each electronic device 22 under test comprises a plurality of conductive contacts 221, 222. The conductive contacts 221, 222 may be realized as bumps or contact pads. In the embodiment of the present invention, the conductive contacts 221, 222 are bumps. Since the conductive contacts 221, 222 are very small in size and large in number, they are omitted from FIG. 1 for simplicity of illustration. FIG. 2 schematically shows one configuration of the conductive contacts 221, 222, in which the conductive contacts 221 have larger areas and a larger pitch thereamong and are disposed in a central region 223 of the electronic device 22 under test, while the conductive contacts 222 have smaller areas and a smaller pitch thereamong and are disposed in a peripheral region 224 of the electronic device 22 under test.

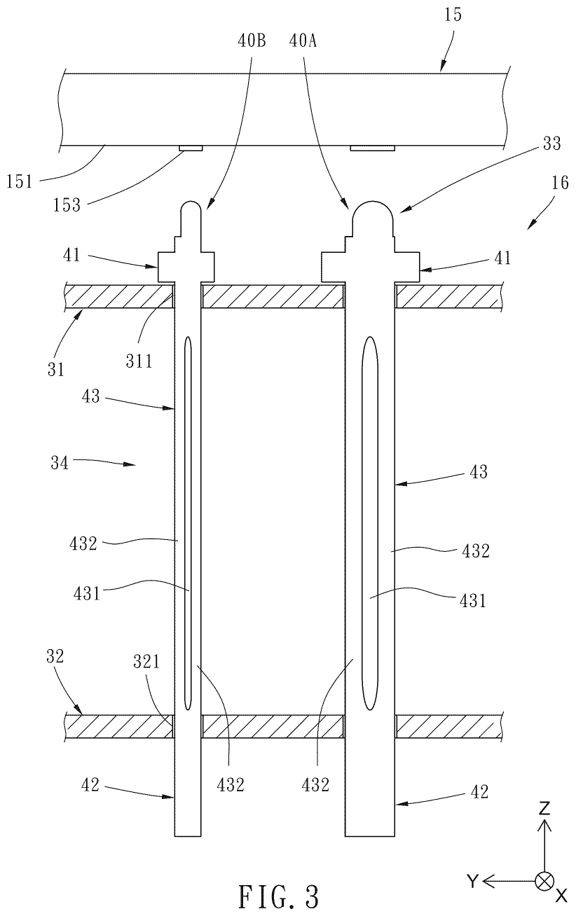

The probe system 10 comprises a chuck 11 for supporting the electronic device 22 under test, a tester 12, and a probe card 13. The probe card 13 comprises a main circuit board 14, a space transformer (ST) 15, and a probe head (PH) 16. The probe head 16 comprises a plurality of probes respectively used to contact the conductive contacts 221, 222 of the electronic device 22 under test (described in detail below). For simplicity of illustration, the probes are not shown in FIG. 1, and the probe head 16 is schematically represented by a rectangle. The internal structure of the probe head 16 is shown in other figures. The main circuit board 14 is used to be electrically connected with the tester 12, and the space transformer 15 is disposed between the probe head 16 and a lower surface 141 of the main circuit board 14 to perform spatial transformation between the probes of the probe head 16 and conductive contacts (not shown) of the lower surface 141 of the main circuit board 14. That is, a lower surface 151 of the space transformer 15 is provided with a plurality of contact pads 153 for electrically contacting the probes (see FIG. 3). The pitch between the contact pads 153 is smaller than the pitch between contact pads (not shown) on an upper surface 152 of the space transformer 15 for electrical connection with the main circuit board 14. Accordingly, when the probes of the probe card 13 contact the conductive contacts 221, 222 of the electronic device 22 under test, the tester 12 is electrically connected with the electronic device 22 under test through the probe card 13, thereby performing an electrical test procedure to test the electrical characteristics of the electronic device 22 under test. More specifically, the present invention provides a method for testing the electronic device 22 under test, comprising the steps of:
(a) providing the probe system 10 as described above;
(b) positioning the probe head 16 at a relative position with respect to the electronic device 22 under test; and
(c) pressing the probe head 16 against the electronic device 22 under test such that the probes of the probe head 16 contact the conductive contacts 221, 222 of the electronic device 22 under test to detect electrical characteristics of the electronic device 22 under test.

As shown in FIG. 3, the probe head 16 comprises an upper guide unit 31, a lower guide unit 32, and a probe unit 33 disposed between the upper guide unit 31 and the lower guide unit 32. The probe unit 33 is, in this embodiment, directed to an assembly of probes for contacting the conductive contacts 221, 222 of an electronic device 22 under test, including a plurality of first probes 40A respectively used to contact the conductive contacts 221, and a plurality of second probes 40B respectively used to contact the conductive contacts 222. For simplicity of illustration, the figures of the present invention schematically show only one first probe 40A and one second probe 40B. Hereinafter, the first probe 40A and the second probe 40B are representative of all the probes in the probe unit 33 for illustration of the technical features of the present invention. However, the probe unit 33 of the present invention is not limited to all of the probes necessarily having the structural features of the first probe 40A and the second probe 40B described below.

In this embodiment, the upper guide unit 31 and the lower guide unit 32 each comprise only one plate. However, the upper guide unit 31 and/or the lower guide unit 32 may also be formed by a plurality of stacked plates. Edges of the upper guide unit 31 and the lower guide unit 32 may be provided with protruding structures and directly connected with each other, or a hollow middle guide (not shown) may be connected between the upper guide unit 31 and the lower guide unit 32. The upper guide unit 31 comprises a plurality of upper guide holes 311, and the lower guide unit 32 comprises a plurality of lower guide holes 321. The first and second probes 40A, 40B have the same length, and each comprises a probe tail 41 and a probe tip 42 respectively located at two ends thereof, and an elongated probe body 43 extending between the probe tail 41 and the probe tip 42. The probe tail 41 is used to mechanically and electrically contact the contact pads 153 of the space transformer 15, and the probe tip 42 is used to mechanically and electrically contact the conductive contacts 221, 222 of the electronic device 22 under test. The probe tails 41 of the first and second probes 40A, 40B are respectively inserted through the upper guide holes 311, the probe tips 42 are respectively inserted through the lower guide holes 321, and the probe bodies 43 are disposed in an accommodating space 34 between the upper guide unit 31 and the lower guide unit 32.

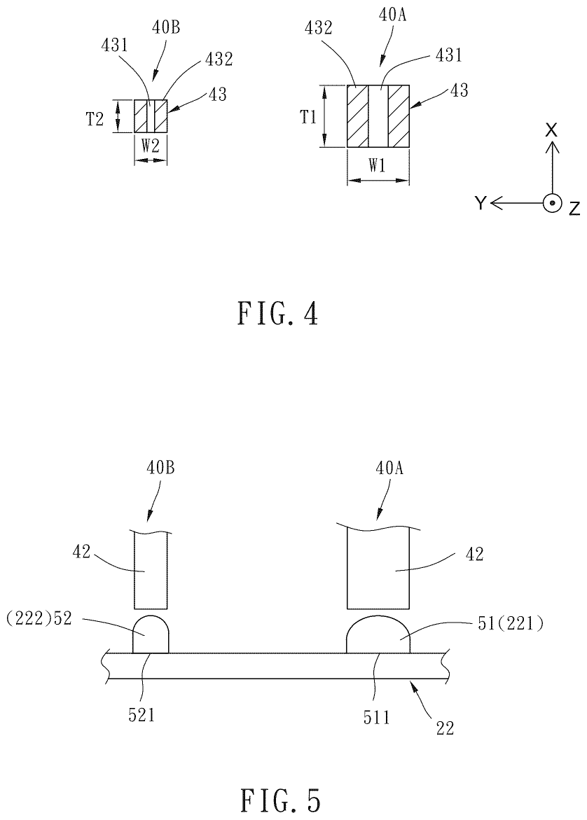

In this embodiment, both the first probe 40A and the second probe 40B are square probes, that is, cross-sectional shapes of their respective portions are square. For example, FIG. 4 shows that the outer contour of the cross-section of the probe bodies 43 of the first and second probes 40A, 40B is square. Further, respective portion of the first and second probes 40A, 40B can define a thickness along a first transverse axis (X-axis), a width along a second transverse axis (Y-axis), and a cross-sectional area on an imaginary plane (X-Y plane) parallel to the first transverse axis and the second transverse axis. For example, FIG. 4 shows widths W1, W2 and thicknesses T1, T2 of the probe bodies 43 of the first and second probes 40A, 40B. In this embodiment, W1=T1 and W2=T2. In addition, the probe bodies 43 of the first and second probes 40A, 40B of this embodiment have a lamellar shape, and such probes are commonly referred to as comb-shaped probes. Specifically, each probe body 43 comprises at least one slot 431 extending along its longitudinal direction (parallel to the Z-axis in FIG. 3). The slot 431 penetrates through the probe body 43 along the first transverse axis (X-axis), such that the probe body 43 is hollow and defined by the at least one slot 431 with at least two slats 432. The at least two slats 432 are separated from each other along the second transverse axis (Y-axis), that is, the at least two slats 432 are arranged in a spaced manner along the second transverse axis (Y-axis). A sum of the cross-sectional areas of the at least two slats 432 is defined as a total cross-sectional area. In this embodiment, the probe body 43 of each probe is provided with only one slot 431, thereby defining two slats 432, and the total cross-sectional area is the sum of the cross-sectional areas of the two slats 432. If the probe body 43 is provided with two slots 431, then three slats 432 are defined, and the total cross-sectional area is the sum of the cross-sectional areas of the three slats 432, and so forth.

During assembly of the probe head 16, the upper guide unit 31 and the lower guide unit 32 are first arranged opposite to each other but not yet fixed together. At this time, the upper guide holes 311 respectively correspond coaxially with the lower guide holes 321, and the first and second probes 40A, 40B are inserted in a straight line through the coaxially corresponding upper guide holes 311 and lower guide holes 321, that is, in the state shown in FIG. 3. After the probes are inserted, the upper guide unit 31 and the lower guide unit 32 are moved relative to each other along the second transverse axis (Y-axis), so that the upper guide holes 311 and the lower guide holes 321 are offset from each other along the Y-axis. As a result, the probe bodies 43 of the first and second probes 40A, 40B bend along the second transverse axis (Y-axis). After the relative movement of the upper guide unit 31 and the lower guide unit 32 is completed, the upper and lower guide units 31, 32 are fixed together. Therefore, when the probe head 16 is fully assembled, each slat 432 of the probe bodies 43 of the first and second probes 40A, 40B remains in a bent state. In this way, the probe bodies 43 have good elasticity, and when the probe tips 42 of the first and second probes 40A, 40B contact the conductive contacts 221, 222 of the electronic device 22 under test, the slats 432 elastically bend under an applied load.

Specifically, when the first and second probes 40A, 40B are used to test the electronic device 22 under test, the probe tips 42 contact the conductive contacts 221, 222 of the electronic device 22 under test and are then relatively displaced toward each other by a testing stroke (overdrive, abbreviated OD; or overtravel, abbreviated OT). This causes the probe bodies 43 of the first and second probes 40A, 40B to be compressed and elastically bent, and the probe tips 42 of the first and second probes 40A, 40B press against the conductive contacts 221, 222 of the electronic device 22 under test. During this process, forces exerted by the probe tips 42 of the first and second probes 40A, 40B on the conductive contacts 221, 222 of the electronic device 22 under test are defined in the present invention as the contact forces of the first and second probes 40A, 40B. The greater the contact force, the smaller the contact resistance between the probe tips 42 and the conductive contacts 221, 222 of the electronic device 22 under test. The method of measuring the contact force is to apply OD/OT to the first and second probes 40A, 40B and then measure force values exerted by the respective probe tips 42 on a force sensor.

Further, the aforementioned contact force includes a probe deformation force and a probe friction force. The probe deformation force refers to the force required for elastic deformation of the probe during the testing stroke described above. The probe deformation force depends on many factors, such as material properties of the probe (e.g., Young's modulus, elastic modulus) and the final geometry and dimensions of the probe (e.g., length, thickness, width, etc.). The probe friction force refers to friction applied to the probe by the guides, such as the friction force applied to the probe by the wall of the upper guide hole 311 and/or the wall of the lower guide hole 321. The aforementioned contact force can reliably push the probe tails 41 of the first and second probes 40A, 40B against the contact pads 153 of the space transformer 15 and then buckle/bend the probe bodies 43 of the first and second probes 40A, 40B. In this way, electrical connection is established between the first and second probes 40A, 40B and the conductive contacts 221, 222 of the electronic device 22 under test, thereby enabling the conductive contacts 221, 222 of the electronic device 22 under test to establish electrical connection through the first and second probes 40A, 40B to the tester 12.

As shown in FIGS. 3 to 5, the first probe 40A and the second probe 40B are respectively a large-sized probe and a small-sized probe. The first probe 40A is used to contact the conductive contacts 221 having larger area and pitch, while the second probe 40B is used to contact the conductive contacts 222 having smaller area and pitch. More specifically, a total cross-sectional area of the slats 432 of the first probe 40A is greater than that of the slats 432 of the second probe 40B. The shapes of the slats 432 of the first probe 40A are different from those of the slats 432 of the second probe 40B (although both have rectangular cross-sectional shapes, their dimensions are different, and are thus regarded as different shapes). The shapes of the slats 432 are especially selected such that a contact force of the first probe 40A is greater than a contact force of the second probe 40B. Preferably, a ratio of the contact force of the first probe 40A to the contact force of the second probe 40B is greater than 1 and smaller than 4. When the ratio is smaller than or equal to 1, that is, when the contact force of the first probe 40A is smaller than or equal to the contact force of the second probe 40B, the contact force of the first probe 40A for contacting the conductive contacts 221 of larger area tends to be insufficient, thereby affecting testing stability. Alternatively, the contact force of the second probe 40B for contacting the conductive contacts 222 of smaller area tends to be excessive, thereby easily damaging the second probe 40B and/or the conductive contacts 222. Furthermore, the problems of inconsistent probe tip wear rates and excessively large differences in probe mark area ratios cannot be avoided. On the other hand, when the ratio is greater than or equal to 4, that is, when the contact force of the first probe 40A is four times or more greater than the contact force of the second probe 40B, the difference between the contact forces of the first probe 40A and the second probe 40B becomes excessively large, which not only tends to affect wear consistency between the first probe 40A and the second probe 40B, but also tends to cause damage to the central region and peripheral region of the space transformer 15 due to extremely uneven forces exerting on the central and peripheral regions, or which may result in that additional reinforcement structure needs to be applied to the central and peripheral regions of the space transformer 15. Moreover, excessive contact force of the first probe 40A also tends to damage the first probe 40A and/or the conductive contacts 221.

In other words, this embodiment adopts a hybrid configuration of different comb-shaped probes, namely the first probe 40A and the second probe 40B. Although the cross-sectional outer contours of the probe bodies 43 of the first and second probes 40A, 40B are square, their dimensions in length and width are different, and thus regarded as different shapes. Specifically, the width W1, thickness T1, and total cross-sectional area of the slats 432 of the probe body 43 of the first probe 40A are greater than the width W2, thickness T2, and total cross-sectional area of the slats 432 of the probe body 43 of the second probe 40B, respectively. In addition, the contact force exerted by the first probe 40A on the conductive contacts 221 is greater than the contact force exerted by the second probe 40B on the conductive contacts 222. The hybridization of different comb-shaped probes may be implemented as follows: both the first and second probes 40A, 40B each have a single slot 431 and two slats 432 (as provided in this embodiment); or the second probe 40B has a single slot 431 and two slats 432, while the first probe 40A has two slots 431 and three slats 432, or more than two slots 431 and more than three slats 432; or the second probe 40B has two slots 431 and three slats 432, while the first probe 40A has a single slot 431 and two slats 432, or two slots 431 and three slats 432, or more than two slots 431 and more than three slats 432; and so forth.

Accordingly, the widths and thicknesses of the first and second probes 40A, 40B can be designed according to the sizes and pitches of the conductive contacts 221, 222 to be contacted, and the rigidity of the probes can be appropriately reduced through the design of the slots 431 of the probe bodies 43 (e.g., slot width, number, etc.), thereby appropriately reducing the contact forces of the probes so that the first and second probes 40A, 40B meet the testing requirements of the corresponding conductive contacts 221, 222 in all aspects. Specifically, the total cross-sectional area of the slats 432 of the first probe 40A is larger, which can satisfy the high current demand of the larger conductive contacts 221, and the larger conductive contacts 221 can withstand the larger contact force of the first probe 40A without being easily damaged. The total cross-sectional area of the slats 432 of the second probe 40B is smaller, which can satisfy the low current demand of the smaller conductive contacts 222, and the smaller contact force of the second probe 40B can prevent damage to the smaller conductive contacts 222. In other words, the slats 432 of the first probe 40A and the second probe 40B have different thickness-to-width ratios in geometry, and such shape difference results in different total cross-sectional areas and further causes different contact force performances. Specifically, the slats 432 of the first probe 40A and the second probe 40B may be formed with different lengths and/or different thicknesses and/or different widths.

More importantly, the present invention may, through dimensional design of the first and second probes 40A, 40B (e.g., widths, thicknesses, slot widths 431, total cross-sectional areas of the slats 432, etc.), harmonize the first and second probes 40A, 40B such that their probe tip wear rates are substantially equal and/or such that they produce substantially equal probe mark area ratios. As defined in the present invention, “substantially equal” means that the difference is less than or equal to 20%. In other words, by dimensional design of the first and second probes 40A, 40B, the ratios of contact force to contact area of the first and second probes 40A, 40B can be made consistent or similar, such that the probe tip wear rates of the first and second probes 40A, 40B are consistent or similar, thereby maintaining consistent or similar lengths of the first and second probes 40A, 40B; and/or the first and second probes 40A, 40B can produce consistent or similar probe mark area ratios on the large bumps (i.e., conductive contacts 221) and small bumps (i.e., conductive contacts 222) contacted thereby, such that the large bumps and the small bumps have consistent or similar heights after testing.

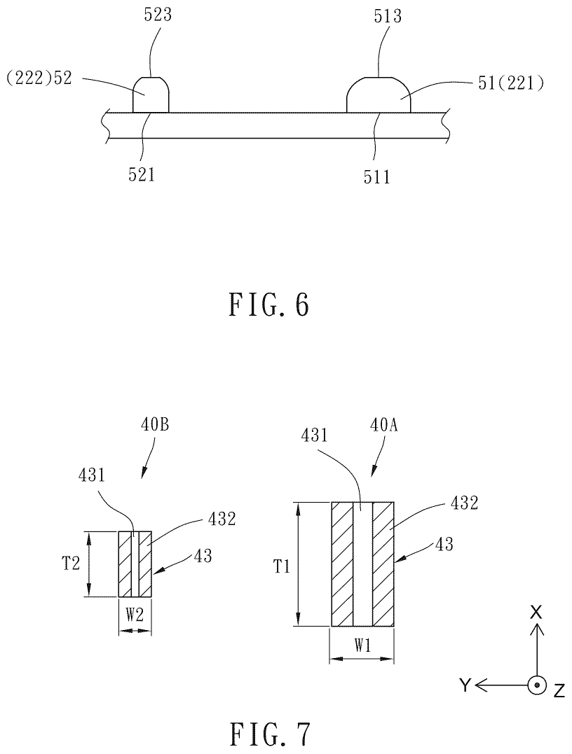

As shown in FIGS. 3 to 5, in this embodiment the conductive contacts 221, 222 are bumps, and are respectively defined as first bumps 51 and second bumps 52. A maximum cross-sectional area of the first bump 51 (i.e., a cross-sectional area of its bottom portion 511) is greater than a maximum cross-sectional area of the second bump 52 (i.e., a cross-sectional area of its bottom portion 521). When the probe tip 42 of the first probe 40A and the probe tip 42 of the second probe 40B respectively press against the first bump 51 and the second bump 52, the probe bodies 43 of the first probe 40A and the second probe 40B are subjected to loads and elastically bent. The probe tips 42 of the first and second probes 40A, 40B partially flatten the first and second bumps 51, 52 and thereby form planar probe marks 513, 523, as shown in FIG. 6 (side view). An area of the probe mark 513 formed by the first probe 40A on the first bump 51 is defined as a first probe mark area, and an area of the probe mark 523 formed by the second probe 40B on the second bump 52 is defined as a second probe mark area. A probe mark area ratio of the first probe 40A is defined as a ratio of the first probe mark area (i.e., an area of the probe mark 513) to the maximum cross-sectional area of the first bump 51 (i.e., the cross-sectional area of the bottom portion 511). A probe mark area ratio of the second probe 40B is defined as a ratio of the second probe mark area (i.e., an area of the probe mark 523) to the maximum cross-sectional area of the second bump 52 (i.e., the cross-sectional area of the bottom portion 521). In this embodiment, the term “probe mark area ratio” refers to a ratio obtained by observing, from a top view of the electronic device 22 under test, a contact area of a probe mark formed on a top surface of a bump, relative to the maximum cross-sectional area of the bump. In other words, the probe mark area ratio is a parameter for measuring the degree of indentation of a probe on the corresponding bump, which can be used to compare deformation ranges of probe marks corresponding to bumps of different sizes. Generally, the maximum cross-sectional area of a bump is defined according to the size of the bump, that is, a nominal size (design value) of the bump. For example, when the bump is a circular bump having a diameter of 20 micrometers, the maximum cross-sectional area can be regarded as a circular area calculated from the diameter. In other words, in this embodiment, the maximum cross-sectional area of the bump is defined by a diameter, a width, or an equivalent geometric dimension (e.g., a projected area) of the bump, and is used as a reference basis for the probe mark area ratio. In some embodiments, the probe mark area can also be inferred from a collapse height of the bump after the bump is contacted by the probe. In general, the ratio of the first probe mark area to the maximum cross-sectional area of the first bump 51 and/or the ratio of the second probe mark area to the maximum cross-sectional area of the second bump 52 is preferably smaller than 25%.

It is worth mentioning that the first and second probes 40A, 40B may also be used to contact first bumps 51 and second bumps 52 of substantially the same size. For example, as shown in FIG. 13, the probe tip 42 of the first probe 40A is used to simultaneously press against a plurality of first bumps 51, for example, four first bumps 51 arranged in a matrix (FIG. 13 shows only two of the first bumps 51). The plurality of first bumps 51 are all configured to transmit a first signal, which may be either a power signal or a ground signal. The probe tip 42 of the second probe 40B is used to press against a single second bump 52, which is configured to transmit a second signal different from the first signal, i.e., a test signal other than the power signal or the ground signal. Accordingly, even when the first bumps 51 and the second bump 52 are of substantially the same size, the first probe 40A with a larger contact force is used to simultaneously press against the plurality of first bumps 51, and the second probe 40B with a smaller contact force is used to press against the single second bump 52. Therefore, by dimensional design, the probe tip wear rates of the first and second probes 40A, 40B can still be made consistent or similar, and/or the first and second probes 40A, 40B can produce consistent or similar probe mark area ratios on the first bumps 51 and the second bump 52.

In addition, the first probe 40A and the second probe 40B may be made of materials having different hardness. By providing different hardness between the first probe 40A and the second probe 40B, the first and second probes 40A, 40B can also be harmonized such that their probe tip wear rates are substantially equal. For example, the second probe 40B having a smaller total cross-sectional area may be made of a harder material so as to slow down its probe tip wear rate. In this embodiment, the term “different hardness” between the first probe 40A and the second probe 40B means that the probe bodies are made of materials having different hardness. The hardness may be measured according to Vickers hardness (HV) or other standard hardness testing methods and presents a certain difference. By using materials of different hardness, the wear rates of probes of different sizes can be coordinated to maintain consistency and long-term stability during testing.

Furthermore, the first probe 40A and the second probe 40B may also have different resistance values, and/or different current-carrying capacity, and/or different resistivity, and/or different conductivity, so as to satisfy testing requirements of different conductive contacts. At the same time, the first probe 40A and the second probe 40B can still be designed such that their contact forces enable their probe tip wear rates to be consistent or similar, and/or enable them to produce consistent or similar probe mark area ratios on the respective conductive contacts contacted thereby.

In this embodiment, the term “resistance value of a probe” refers to an electrical impedance generated by a conductive material of the probe under its designed length and cross-sectional area conditions when current flows therethrough, usually expressed in ohms (52). In other words, the resistance value is a comprehensive expression of the geometric dimensions of the probe and its material property (resistivity), and is applicable for comparing conductive capacities of individual probes of different sizes or materials. The resistance value of a probe can be calculated by the formula R=ρ(L/A), where R is the resistance value of the probe, L is the length of the probe, A is the cross-sectional area of the probe, and ρ is the resistivity of the probe material. For example, when the first probe 40A and the second probe 40B are made of the same material but have different dimensions, the resistance values are primarily determined by differences in geometric dimensions. Generally, a large-sized probe with a larger cross-sectional area (i.e., the first probe 40A) has a lower resistance value, while a small-sized probe with a smaller cross-sectional area (i.e., the second probe 40B) has a higher resistance value.

In this embodiment, the term “current-carrying capacity” refers to a maximum current that a single probe can continuously withstand under stable operating conditions without causing overheating, structural damage, or material degradation, and is usually expressed in milliamperes (mA). In other words, the current-carrying capacity is a comprehensive index determined by structural dimensions, thermal conductivity of the material, and heat dissipation conditions. In this embodiment, the current-carrying capability of a probe is collectively affected by factors such as the cross-sectional area, length, melting point of the material, and thermal conductivity of the probe. Generally, a large-sized probe with a larger cross-sectional area has better heat dissipation efficiency and current-withstanding capability, and thus its current-carrying capacity is usually higher than that of a small-sized probe. For example, if the first probe 40A is a large-sized probe and the second probe 40B is a small-sized probe, then under the same material and testing conditions, the current-carrying capability of the first probe 40A is expected to be higher than that of the second probe 40B, that is, the first probe 40A can withstand a larger current without being damaged by thermal effects.

In this embodiment, the term “resistivity” refers to an inherent physical property of a material indicating its resistance to current conduction, usually expressed in ohm-meters (Ω·m). A higher resistivity means that the material provides greater obstruction to current flow, whereas a lower resistivity indicates better conductivity. On the other hand, conductivity is the reciprocal of resistivity, representing the ability of a material to conduct current, usually expressed in siemens per meter (S/m). A higher conductivity means the material is more conductive. In the present invention, when the first probe 40A and the second probe 40B have different resistivity or conductivity, it indicates that the first and second probes 40A, 40B are made of different conductive materials. Such material differences can be used to achieve optimized probe design under different current conditions. For example, probes intended for high current demand may use materials with lower resistivity to reduce Joule heating loss, while probes intended for low current demand may use materials with higher mechanical strength to improve service life and accuracy.

In the present invention, the first probe 40A and the second probe 40B are not limited to square-shaped probes, that is, the cross-sectional shapes of their parts are not limited to being square. For example, as shown in FIG. 7, the probe bodies 43 of the first and second probes 40A, 40B may have rectangular cross-sectional outer contours, wherein the widths of the probe bodies 43 are smaller than their thicknesses, that is, W1<T1 and W2<T2. In other words, the longer side of the rectangle corresponds to the thickness direction of the probe, i.e., the first transverse axis (X-axis). Such a design allows the probe bodies 43 to have better elastic deformation performance when bending along the second transverse axis (Y-axis), while still maintaining sufficient thickness of the probe bodies 43 to ensure a certain level of current-carrying capacity.

Furthermore, in the first and second probes 40A, 40B shown in FIG. 7, since the total cross-sectional area of the slats 432 of the first probe 40A is greater than that of the slats 432 of the second probe 40B, the first probe 40A is a probe with a larger needle diameter, while the second probe 40B is a probe with a smaller needle diameter. Generally, probes with smaller needle diameters also have relatively smaller interval between probes, and thus their needle diameter dimensions (width and/or thickness) cannot be arbitrarily increased, in order to avoid excessively small probe interval that may cause short-circuiting between probes, or insufficient wall thickness of the guide due to excessively small interval between guide holes. Based on this design consideration, the ratio of width W1 to thickness T1 of the probe body 43 of the first probe 40A is designed to be smaller than the ratio of width W2 to thickness T2 of the probe body 43 of the second probe 40B, that is, W1/T1<W2/T2. Alternatively, the probe body 43 of the first probe 40A may have a rectangular cross-sectional outer contour, while the probe body 43 of the second probe 40B may have a square cross-sectional outer contour, thereby achieving the above-mentioned ratio relationship as a structural feature. Accordingly, the probe body 43 of the first probe 40A, while maintaining a larger cross-sectional area to withstand higher current, has a smaller width-to-thickness ratio and thus possesses better elastic deformation performance when bending along the second transverse axis, so that it can produce a consistent or similar elastic deformation response with the second probe 40B having a smaller cross-sectional area, thereby ensuring consistent or similar probing performance of both probes.

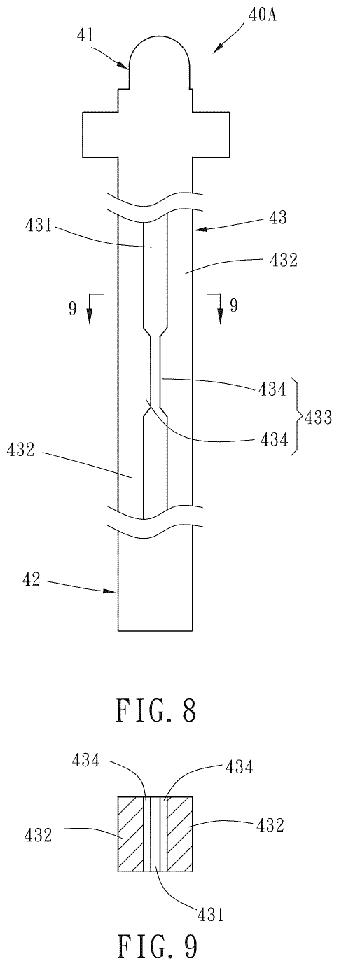

Furthermore, the comb-shaped probes of the present invention may also have structural features as shown in FIGS. 8 and 9. Taking the first probe 40A as an example, at least one protrusion set 433 may be disposed in the slot 431, the protrusion set 433 comprising two protrusions 434 that protrude from two adjacent slats 432 toward each other in a mutually facing manner. Accordingly, when the probe tip 42 of the first probe 40A presses against a conductive contact 221 of the electronic device 22 under test and the slats 432 of the probe body 43 are subjected to a load and thus elastically bent, the two face-to-face protrusions 434 in the slot 431 will be abutted against each other, thereby preventing the adjacent slats 432 from contacting and wearing against each other, and thus improving the service life of the probe. Moreover, by abutting the face-to-face protrusions 434 against each other, the slats 432 can be maintained with a consistent deflection direction and a certain interval, which contributes to stable electrical performance in high-frequency and high-speed testing. With the feature that the protrusions 434 are disposed between adjacent slats 432 and arranged in a face-to-face manner, when the probe bends, the protrusions 434 come into contact first, thereby limiting the bending direction and angle of the slats 432. As a result, asymmetric deflection of the slats 432 under eccentric loading can be avoided, ensuring a stable contact angle of the probe tip with the pad or bump, and contributing to consistent probe marks and stable contact resistance.

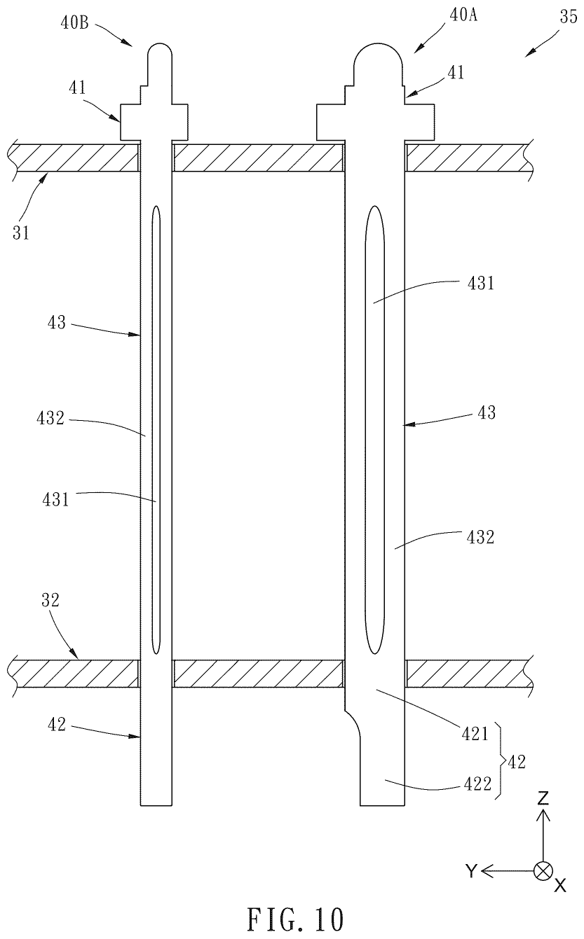

Referring to FIG. 10, a probe unit 35vb provided by a second preferred embodiment of the present invention is similar to the aforesaid probe unit 33, except that the difference lies in the shape of the probe tip 42 of the first probe 40A.

Specifically, in this embodiment, the probe tip 42 of the first probe 40A includes a base portion 421 connected with the probe body 43, and an end portion 422 connected with the base portion 421. The cross-sectional shape of the base portion 421 is the same as, or substantially the same as, the outer contour shape of the cross-section of the probe body 43. The term “substantially the same” means that the area difference is within ±20%. Compared with the base portion 421, the end portion 422 is reduced in width and/or thickness, such that the cross-sectional area of the end portion 422 is smaller than that of the base portion 421. Preferably, the cross-sectional area of the end portion 422 is 20-60% of that of the base portion 421, and more preferably about 50% of that of the base portion 421. The end portion 422 serves as the actual contacting tip of the probe tip 42 of the first probe 40A for contacting the conductive contact 221 of the electronic device 22 under test. As shown in FIG. 10, the end portion 422 is preferably located eccentrically with respect to the center of the first probe 40A, or eccentrically with respect to the base portion 421, and may be formed by asymmetrically (unilaterally/in one direction) removing material from one side of the probe tip 42 of the first probe 40A.

With this structural design, the shapes of the slats 432 of the first probe 40A and the second probe 40B can still be selected in such a way that the contact force of the first probe 40A with a larger total cross-sectional area is greater than that of the second probe 40B with a smaller total cross-sectional area. Preferably, the ratio of the contact force of the first probe 40A to that of the second probe 40B is greater than 1 and less than 4. In addition, the probe tip 42 of the first probe 40A has a thinned and/or narrowed end portion 422, which helps adjust the probe tip wear rate of the first probe 40A and the probe mark area ratio generated thereby, thereby enabling the probe tip wear rates of the first and second probes 40A, 40B to be consistent or similar, and/or enabling the first and second probes 40A, 40B to generate consistent or similar probe mark area ratios. In particular, such design makes it easier to tune the first and second probes 40A, 40B to achieve substantially equal probe mark area ratios.

Furthermore, even if the cross-sectional area of the end portion 422 of the probe tip 42 of the first probe 40A is reduced, the cross-sectional area of the end portion 422 of the probe tip 42 of the first probe 40A can still be larger than that of the probe tip 42 of the second probe 40B. In this way, the first and second probes 40A, 40B can still respectively correspond to larger conductive contacts 221 and smaller conductive contacts 222, while contributing to making the probe tip wear rates of the first and second probes 40A, 40B consistent or similar, and also making the probe mark area ratios of the first and second probes 40A, 40B consistent or similar. Preferably, the ratio of the cross-sectional area of the end portion 422 of the probe tip 42 of the first probe 40A to the cross-sectional area of the probe tip 42 of the second probe 40B is greater than 1 and less than 4. When the aforesaid ratio is less than 1, that is, when the cross-sectional area of the end portion 422 of the probe tip 42 of the first probe 40A is smaller than that of the probe tip 42 of the second probe 40B, it is difficult to avoid the problems of inconsistent probe tip wear rates and excessively large differences in probe mark area ratios. Conversely, when the aforesaid ratio is greater than or equal to 4, that is, when the cross-sectional area of the end portion 422 of the probe tip 42 of the first probe 40A is greater than or equal to four times that of the probe tip 42 of the second probe 40B, the difference is excessively large, which not only adversely affects the consistency of wear between the first and second probes 40A, 40B, but also makes it difficult to avoid excessively large differences in probe mark area ratios.

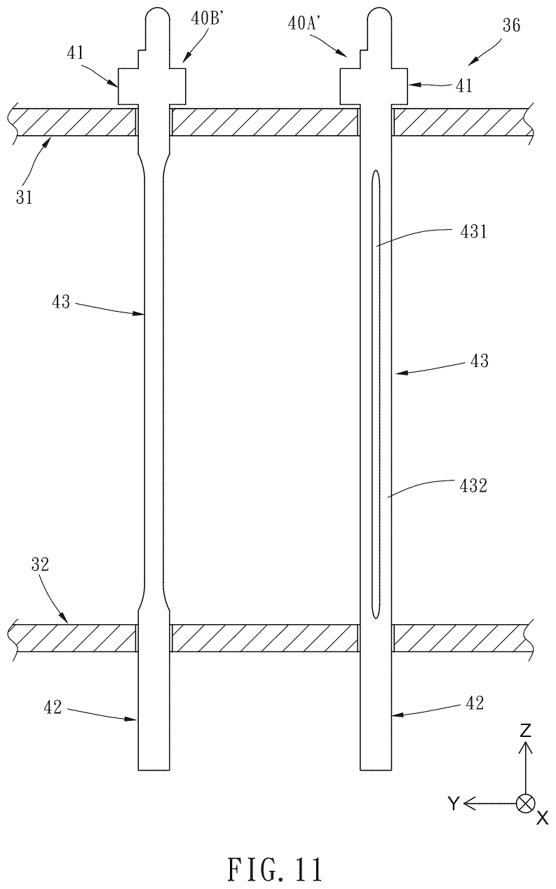

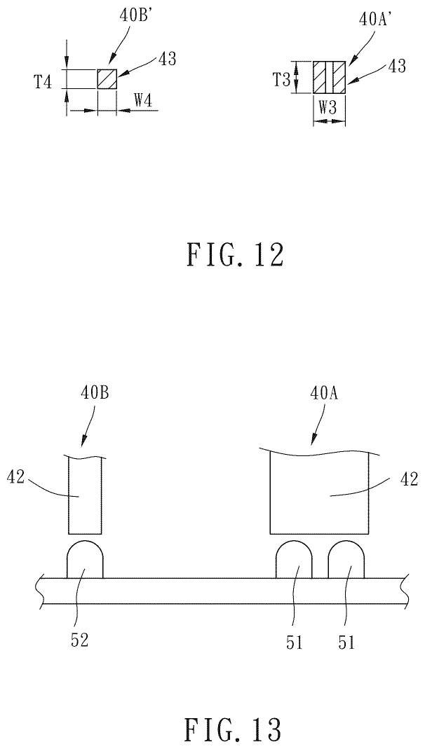

FIGS. 11 and 12 depicts a probe unit 36 provided by a third preferred embodiment of the present invention, which is primarily different from the aforesaid embodiments in that in this embodiment the first probe 40A′ is likewise a comb-shaped probe, but the second probe 40B′ is a non-comb-shaped probe, and the probe body 43 of the second probe 40B′ has a recessed configuration, as detailed below.

In this embodiment, the first probe 40A′ is similar in shape and size to the second probe 40B of the aforesaid embodiments. The probe body 43 of the first probe 40A′ comprises at least one slot 431 extending along its longitudinal direction, and the slot 431 penetrates through the probe body 43 of the first probe 40A′ along the first transverse axis (X-axis), such that the probe body 43 of the first probe 40A′ is hollow and defined by the at least one slot 431 with at least two slats 432 separated from each other along the second transverse axis (Y-axis) and elastically bendable under an applied load. Similar to the comb-shaped probes in the first preferred embodiment, the probe body 43 of the first probe 40A′ may have a width W3 equal to a thickness T1 (i.e., a square cross-sectional outline), or the width W3 may be smaller than the thickness T1 (i.e., a rectangular cross-sectional outline) to enhance the elastic bending performance of the probe body 43 along the second transverse axis (Y-axis) and provide sufficient thickness to reduce the risk of breakage. The first probe 40A′ in this embodiment may also be provided with a protrusion set 433 as shown in FIGS. 8 and 9, thereby enhancing the service life of the probe and improving electrical performance in high-frequency, high-speed testing.

In this embodiment, the probe tail 41 and probe tip 42 of the second probe 40B′ are similar in shape and size to those of the first probe 40A′. However, the probe body 43 of the second probe 40B′ is not provided with a slot but is solid, and the probe body 43 of the second probe 40B′ is recessed in width and/or thickness relative to the probe tail 41 and the probe tip 42, such that the cross-sectional area of the probe body 43 of the second probe 40B′ is smaller than that of the probe tail 41 of the second probe 40B′ and smaller than that of the probe tip 42 of the second probe 40B′. The recessed configuration of the probe body 43 of the second probe 40B′ relative to the probe tail 41 and the probe tip 42 may be unilateral, bilateral, or on all four sides. In this way, the probe body 43 of the second probe 40B′ can also be elastically bent when mounted between the upper and lower guide units 31, 32, and can exhibit good elasticity to elastically bend under an applied load when the probe tip 42 presses against the electronic device 22 under test.

In other words, this embodiment adopts a hybrid configuration of a comb-shaped probe and a non-comb-shaped probe, namely the first and second probes 40A′, 40B′. The probe bodies 43 of the first and second probes 40A′, 40B′ both have square cross-sectional outlines, but their lengths and widths differ and are therefore regarded as different shapes. Specifically, the width W3 and thickness T3 of the probe body 43 of the first probe 40A′ are greater than the width W4 and thickness T4 of the probe body 43 of the second probe 40B′, respectively, and the total cross-sectional area of the slats 432 of the first probe 40A′ is greater than the cross-sectional area of the probe body 43 of the second probe 40B′. The slats 432 of the first probe 40A′ are configured in such a way that the contact force of the first probe 40A′ is greater than that of the second probe 40B′.

Accordingly, the first and second probes 40A′, 40B′ of this embodiment can also be dimensionally designed to meet the testing requirements of the respective conductive contacts 221, 222. Specifically, the total cross-sectional area of the slats 432 of the first probe 40A′ is larger and can meet the high-current demand of the larger conductive contacts 221, and the larger conductive contacts 221 can withstand the greater contact force of the first probe 40A′ without being easily damaged. The cross-sectional area of the probe body 43 of the second probe 40B′ is smaller and can meet the low-current demand of the smaller conductive contacts 222, and the smaller contact force of the second probe 40B′ can prevent damage to the smaller conductive contacts 222. More importantly, this embodiment can also, through dimensional design of the first and second probes 40A′, 40B′, harmonize the probe tip wear rates of the first and second probes 40A′, 40B′ to be substantially equal, and/or produce substantially equal probe mark area ratios. Furthermore, the first probe 40A′ and the second probe 40B′ may be made of materials with different hardness. The difference in hardness between the first probe 40A′ and the second probe 40B′ likewise helps harmonize the probe tip wear rates of the first and second probes 40A′, 40B′ to be substantially equal. As used in this embodiment, the phrase “different hardness” of the first probe 40A′ and the second probe 40B′ means that the probe bodies are made of materials having different hardness. The hardness may be measured by Vickers hardness (HV) or other standardized hardness test methods and should have a certain difference. By selecting materials of different hardness, the wear rates of probes of different sizes can be coordinated, ensuring consistency and long-term stability during testing.

In the embodiments of the present invention, the phrase “different shapes” means that the slats of the first probe and the second probe exhibit identifiable differences in geometric profile, dimensional proportions, or cross-sectional distribution. For example, even if the cross sections of the slats of the first and second probes are both rectangular, they are deemed to have “different shapes” as long as their thickness and width (i.e., the dimensions defined along the first transverse axis and the second transverse axis) are different. In addition, even where the number of slats is the same, differences in their distribution, the number of slots, thickness-to-width ratios, and/or symmetry configurations likewise fall within the “different shapes” described herein. Such design differences help tune the contact-force distribution and elastic deformation behavior of the respective probes, thereby ensuring testing accuracy and reliability for different conductive contacts (e.g., large bumps and small contact pads).

Finally, it should be noted again that the constituent elements disclosed in the foregoing embodiments are provided by way of example and are not intended to limit the scope of the present application. Substitutions or modifications using other equivalent elements are also intended to be encompassed within the scope of the claims of this application.

What is claimed is:

1. A probe unit for contacting a plurality of conductive contacts of an electronic device under test integrated in a semiconductor wafer; the probe unit comprising:
a plurality of probes each having a same length and each including a probe tail and a probe tip respectively located at two ends thereof, and a probe body between the probe tail and the probe tip;
wherein the probe body comprises at least one slot extending along a longitudinal direction thereof and penetrating through the probe body along a first transverse axis, such that the probe body is hollow and defined by the at least one slot with at least two slats separated from each other along a second transverse axis and elastically bendable under an applied load; each of the slats has a cross-sectional area on an imaginary plane parallel to the first transverse axis and the second transverse axis, and a sum of the cross-sectional areas of the at least two slats of each of the probes is defined as a total cross-sectional area;
wherein the plurality of probes include a first probe and a second probe, the total cross-sectional area of the slats of the first probe is greater than the total cross-sectional area of the slats of the second probe, the slats of the first probe have shapes different from that of the slats of the second probe, and the shapes of the slats of the first and second probes are configured such that a contact force of the first probe is greater than a contact force of the second probe.

2. The probe unit as claimed in claim 1, wherein a ratio of the contact force of the first probe to the contact force of the second probe is greater than 1 and less than 4.

3. The probe unit as claimed in claim 1, wherein the probe body of each of the probes defines a thickness along the first transverse axis and a width along the second transverse axis, and the width of the probe body of each of the probes is less than or equal to the thickness.

4. The probe unit as claimed in claim 1, wherein the probe tip of the first probe comprises a base portion that is connected to the probe body, and an end portion that is connected to the base portion for contacting the conductive contact of the electronic device under test; the base portion and the end portion respectively define cross-sectional areas on an imaginary plane parallel to the first transverse axis and the second transverse axis, and the cross-sectional area of the end portion is smaller than the cross-sectional area of the base portion.

5. The probe unit as claimed in claim 4, wherein the probe tip of the second probe defines a cross-sectional area on an imaginary plane parallel to the first transverse axis and the second transverse axis, and the cross-sectional area of the end portion of the probe tip of the first probe is greater than or equal to the cross-sectional area of the probe tip of the second probe.

6. The probe unit as claimed in claim 5, wherein a ratio of the cross-sectional area of the end portion of the probe tip of the first probe to the cross-sectional area of the probe tip of the second probe is greater than 1 and less than 4.

7. The probe unit as claimed in claim 1, wherein the plurality of conductive contacts of the electronic device under test include a first bump and a second bump, and a maximum cross-sectional area of the first bump is greater than a maximum cross-sectional area of the second bump; when the probe tip of the first probe and the probe tip of the second probe respectively press against the first bump and the second bump so that the probe body of the first probe and the probe body of the second probe are subjected to a load and elastically bent, the first probe forms a first probe mark area on the first bump, and the second probe forms a second probe mark area on the second bump, and a ratio of the first probe mark area to the maximum cross-sectional area of the first bump and a ratio of the second probe mark area to the maximum cross-sectional area of the second bump are substantially equal.

8. The probe unit as claimed in claim 1, wherein the plurality of conductive contacts of the electronic device under test include a plurality of first bumps and a second bump, and each of the plurality of first bumps has substantially the same size as the second bump; the probe tip of the first probe is for simultaneously pressing against the plurality of first bumps that are configured to transmit a first signal, which is one of a power signal and a ground signal; the probe tip of the second probe is for pressing against the second bump that is configured to transmit a second signal different from the first signal, the second signal being a test signal.

9. The probe unit as claimed in claim 1, wherein the probe body of each of the probes defines a thickness along the first transverse axis and a width along the second transverse axis, and a ratio of the width to the thickness of the probe body of the first probe is smaller than a ratio of the width to the thickness of the probe body of the second probe.

10. The probe unit as claimed in claim 1, wherein the first probe and the second probe have different material hardness.

11. The probe unit as claimed in claim 10, wherein the material hardness of the second probe is greater than the material hardness of the first probe.

12. The probe unit as claimed in claim 1, wherein at least the slot of the first probe is disposed with at least one protrusion set including two protrusions protruding from two adjacent said slats toward each other.

13. A probe head applied to a probe system for testing an electronic device under test integrated in a semiconductor wafer; the probe head comprising:
an upper guide unit comprising a plurality of upper guide holes;
a lower guide unit comprising a plurality of lower guide holes; and
a probe unit as claimed in claim 1;
wherein the probe tails of the plurality of probes are respectively inserted through the upper guide holes, the probe tips of the plurality of probes are respectively inserted through the lower guide holes, and the probe bodies of the plurality of probes bend along the second transverse axis.

14. A probe card applied to a probe system for testing an electronic device under test integrated in a semiconductor wafer; the probe card comprising:
the probe head as claimed in claim 13;
a space transformer; and
a main circuit board;
wherein the space transformer is disposed on a lower surface of the main circuit board, the space transformer comprises a lower surface and a plurality of contact pads on the lower surface, and the probe tails of the plurality of probes of the probe head mechanically and electrically contact the contact pads of the space transformer.

15. A probe system for testing an electronic device under test integrated in a semiconductor wafer; the probe system comprising:
a chuck for supporting the electronic device under test;
a tester; and
the probe card as claimed in claim 14 electrically connected with the tester and configured to contact the electronic device under test so as to electrically connect the tester to the electronic device under test and thereby perform an electrical test procedure.

16. A method of performing test on an electronic device under test, comprising:
(a) providing the probe system as claimed in claim 15;
(b) positioning the probe head related to the electronic device under test; and
(c) pressing the probe head to make contact with the electronic device under test to detect one of electronic characteristics of the electronic device under test.

17. An electronic device tested by the method as claimed in claim 16.

18. A probe unit for contacting a plurality of conductive contacts of an electronic device under test integrated in a semiconductor wafer; the probe unit comprising:
a plurality of probes each having a same length and each including a probe tail and a probe tip respectively located at two ends thereof, and a probe body between the probe tail and the probe tip; wherein the plurality of probes comprises;
a first probe, the probe body of which comprises at least one slot extending along a longitudinal direction thereof and penetrating through the probe body of the first probe along a first transverse axis, such that the probe body of the first probe is hollow and defined by the at least one slot with at least two slats separated from each other along a second transverse axis and elastically bendable under an applied load; and
a second probe, the probe body of which is solid and elastically bendable under an applied load;
wherein the probe tail and the probe tip of each of the probes, each of the slats of the first probe, and the probe body of the second probe respectively define a cross-sectional area on an imaginary plane parallel to the first transverse axis and the second transverse axis; a sum of the cross-sectional areas of the at least two slats of the first probe is defined as a total cross-sectional area; the total cross-sectional area of the slats of the first probe is greater than the cross-sectional area of the probe body of the second probe; the cross-sectional area of the probe body of the second probe is smaller than the cross-sectional area of the probe tail of the second probe and smaller than the cross-sectional area of the probe tip of the second probe; and shapes of the slats of the first probe are configured such that a contact force of the first probe is greater than a contact force of the second probe.

19. The probe unit as claimed in claim 18, wherein the probe body of the first probe defines a thickness along the first transverse axis and a width along the second transverse axis, and the width of the probe body of the first probe is less than or equal to the thickness.

20. The probe unit as claimed in claim 18, wherein the first probe and the second probe have different material hardness.

21. The probe unit as claimed in claim 20, wherein the material hardness of the second probe is greater than the material hardness of the first probe.
